(19) United States
(12) Patent Application Publication
(10) Pub. No.: US 2010/0307582 A1
(43) Pub. Date: Dec. 9, 2010

(54) PHOTOELECTRIC CONVERSION DEVICE

(75) Inventor: Yasuyuki ARAI, Atsuki (JP)

Correspondence Address: FISH & RICHARDSON P.C. (DC), P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/788,744

(22) Filed: May 27, 2010

(30) Foreign Application Priority Data
Jun. 5, 2009 (JP) 2009-136279

(51) Int. Cl. H01L 31/00

(52) U.S. Cl. 136/256

(57) ABSTRACT

A photoelectric conversion device which is thin, lightweight, and flexible even in the case of using a crystalline semiconductor such as single crystal silicon. A photoelectric conversion layer is provided in contact with an insulating film provided on one surface of a support substrate. An electrode (rear electrode) which is in contact with one surface of the photoelectric conversion layer is provided in accordance with a opening which passes through the support substrate and the insulating film. The rear electrode is in electrical contact with the photoelectric conversion layer and the support substrate. On the other surface of the photoelectric conversion layer, an electrode (surface electrode) on a light incidence side is provided. The photoelectric conversion layer is formed using a semiconductor material; preferably, a single crystal semiconductor or a polycrystalline semiconductor is used.

### BACKGROUND OF THE INVENTION

1. Field of the Invention

The present invention relates to a photoelectric conversion device using a photovoltaic effect of a semiconductor.

2. Description of the Related Art

Increasing consciousness of protection of the global environment through emission reduction of carbon dioxide draws attention to hybrid vehicles. Further, development of electric vehicles that are not powered by an internal-combustion engine has also been advanced. Regarding a photoelectric conversion device used as a power source for vehicles which are driven by electricity, not only high conversion efficiency of solar energy, but also lightness and installation so as to fit a curve of the vehicle body have been demanded.

The following has been disclosed in Patent Document 1: a flexible solar cell in which amorphous silicon is formed on a plastic film substrate or a metal film substrate is used as a photoelectric conversion device for vehicles, for the above-described purpose (see Patent Document 1). However, while being lightweight and able to be installed on the curved surface, photoelectric conversion devices using amorphous silicon are poor in the conversion efficiency and are not suitable for installation in a limited area of vehicles or the like.

A photoelectric conversion device has been disclosed in Patent Document 2, in which single crystal solar cells that are known to have high conversion efficiency are connected by a conductor and the front side and the rear side are sealed by a polyurethane resin so that the weight can be reduced (see Patent Document 2). However, a single crystal solar cell itself with a thickness of hundreds of micrometers is not flexible and is inferior in thickness and flexibility of a photoelectric conversion device, as compared with the case of an amorphous silicon solar cell.

Although a solar cell using a silicon-on-insulator (SOI) structure in which the thickness of a single crystal silicon layer is greater than or equal to 0.1 μm and less than or equal to 5 μm has also be developed, a thick glass substrate is needed as a support substrate by which the single crystal silicon layer is fixed (see Patent Document 3). That is, the thickness of a single crystal silicon layer has been reduced, but the thickness of a photoelectric conversion device as a whole has not been reduced yet.

### REFERENCE

Patent Document 1: Japanese Published Patent Application No. Hei10-181483
Patent Document 2: U.S. Pat. No. 7,049,803

### Patent Document 3: Japanese Published Patent Application No. 2008-112843

### SUMMARY OF THE INVENTION

It is an object of the present invention to provide a photoelectric conversion device which is thin, lightweight, and flexible even in the case of using a crystalline semiconductor such as single crystal silicon.

A photoelectric conversion device according to one embodiment of the present invention is a photoelectric conversion device in which a photoelectric conversion layer is in contact with an insulating film provided on one surface of a support substrate. A opening is formed in the support substrate and the insulating film on the one surface of the support substrate. An electrode (rear electrode) which is provided on a surface (rear surface) on the side opposite to the light incidence side of the photoelectric conversion device is provided on a surface of the support substrate on the side which is opposite to the side where the photoelectric conversion layer is provided. The electrode (rear electrode) is in contact with the photoelectric conversion layer in the opening. The electrode (rear electrode) is in electrical contact with the photoelectric conversion layer and the support substrate. On the light incidence side of the photoelectric conversion device, an electrode (surface electrode) which is in contact with the photoelectric conversion layer is provided. The photoelectric conversion layer is formed using a semiconductor material; preferably, a single crystal semiconductor or a polycrystalline semiconductor is used.

The insulating film is in contact with the support substrate and the photoelectric conversion layer, and these are bonded to each other by atomic force or intermolecular force. That is, the insulating film is provided between the support substrate and the photoelectric conversion layer and may include a plurality of layers.

The support substrate may be a conductive support substrate or an insulating support substrate. A metal material is typically used as the conductive support substrate; a single metal such as aluminum, titanium, copper, or nickel or an alloy containing at least one of these metals is selected as the metal material. As an iron-based material, a stainless steel plate, or a rolled steel plate, a high-tensile steel plate, or the like which is used for a body of automobiles or the like, or the like can be used. The insulating support substrate is formed using a glass material, a plastic material, a ceramic material, or the like.

In this specification, a “single crystal” means a crystal which has aligned crystal faces or aligned crystal axes and in which atoms or molecules constituting the crystal are arranged in a spatially regular manner. However, although single crystals are structured by orderly aligned atoms, single crystals may include disorder such as a lattice defect in which the alignment is partially disordered, or intended or unintended lattice distortion.

Further, an “embrittlement layer” in this specification refers to a region at which a single crystal semiconductor substrate is divided into a single crystal semiconductor layer and a separation substrate (a single crystal semiconductor substrate) in a separation step, and its vicinity. The state of the “embrittlement layer” varies according to a means for forming the “embrittlement layer”. For example, the “embrittlement layer” is a region in which the crystal structure is disordered to be embrittled. Note that a region from the surface side of the single crystal semiconductor substrate to the “embrittlement layer” is somewhat embrittled in some cases; however, the “embrittlement layer” in this specification refers to a region at which division is caused later and its vicinity.

A “photoelectric conversion layer” in this specification includes in its category a semiconductor layer by which a photoelectric (internal photoelectric) effect is achieved and moreover an impurity semiconductor layer bonded for forming an internal electric field or a semiconductor junction. That is to say, the photoelectric conversion layer refers to a semiconductor layer having a junction typified by a pn junction, a pin junction, or the like.

In this specification, numerals such as “first”, “second”, and “third” are given for convenience in order to distinguish elements, and do not limit the number, the arrangement, and the order of steps.

In the photoelectric conversion device according to one embodiment of the present invention, the rear electrode is provided on the rear surface of the support substrate and is in contact with the photoelectric conversion layer by passing through the opening, by which the rear surface (the surface on the side which is opposite to the light incidence side) of the photoelectric conversion device can be effectively used. Accordingly, in the photoelectric conversion device, the active area which contributes to photoelectric conversion can be increased and the effective output per unit area can be increased.

In the photoelectric conversion device according to one embodiment of the present invention, the insulating film is formed over one surface of the support substrate and bonded to the photoelectric conversion layer; accordingly, the photoelectric conversion device which is thin and lightweight can be provided. The rear electrode is provided on the rear surface of the support substrate and is made to be in contact with the photoelectric conversion layer by the opening provided, so that the bonding strength between the photoelectric conversion layer and the support substrate can be enhanced.

According to one embodiment of the present invention, the photoelectric conversion device which is flexible and includes the photoelectric conversion layer firmly fixed to the support substrate can be provided.

### BRIEF DESCRIPTION OF THE DRAWINGS

FIGS. 1A and 1B are plan views illustrating one mode of a photoelectric conversion device according to an embodiment.

FIG. 2 is a cross-sectional view illustrating one mode of a photoelectric conversion device according to an embodiment.

FIGS. 3A and 3B are plan views illustrating one mode of a photoelectric conversion device according to an embodiment.

FIG. 4 is a cross-sectional view illustrating one mode of a photoelectric conversion device according to an embodiment.

FIG. 5A is a plan view illustrating one mode of a photoelectric conversion device according to an embodiment, and FIGS. 5B and 5C are cross-sectional views thereof.

FIGS. 6A and 6B are cross-sectional views illustrating a manufacturing method of a photoelectric conversion device according to an embodiment.

FIGS. 7A and 7B are cross-sectional views illustrating a manufacturing method of a photoelectric conversion device according to an embodiment.

FIGS. 8A and 8B are cross-sectional views illustrating a manufacturing method of a photoelectric conversion device according to an embodiment.

FIGS. 9A and 9B are cross-sectional views illustrating a manufacturing method of a photoelectric conversion device according to an embodiment.

FIGS. 10A and 10B are views each illustrating one example of providing a photoelectric conversion device according to an embodiment for an automobile.

### DETAILED DESCRIPTION OF THE INVENTION

Hereinafter, embodiments of the present invention will be described with reference to accompanying drawings. Note that the present invention is not limited to the description below, and it is easily understood by those skilled in the art that a variety of changes and modifications can be made without departing from the spirit and scope of the present invention. Therefore, the present invention is not to be construed as being limited to the description of the embodiments below.

In the embodiments below, the same parts may be denoted by the same reference numerals throughout the drawings. Note that the thickness, the width, a relative position, and the like of components, that is, layers, regions, and the like illustrated in the drawings are exaggerated in some cases for clarification in the description of the embodiments.

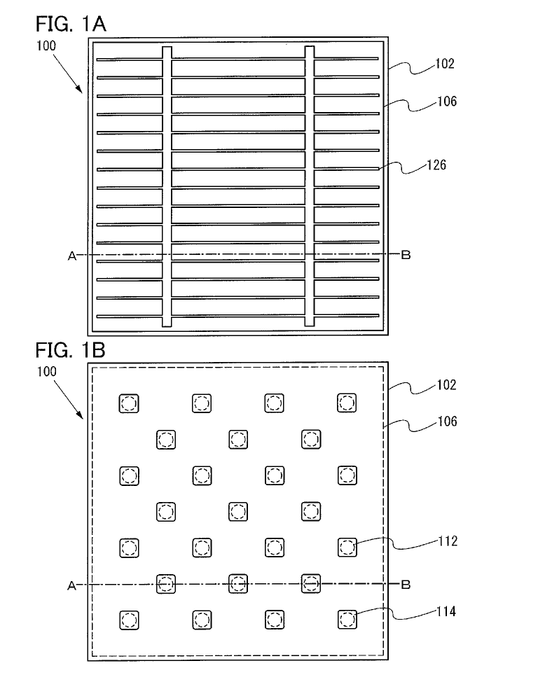

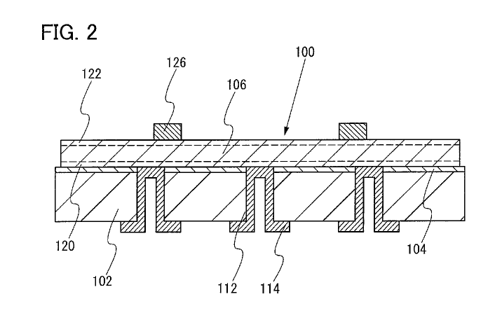

One mode of a photoelectric conversion device according to one embodiment will be described with reference to FIGS. 1A and 1B and FIG. 2. FIG. 1A is a plan view on the side for light reception of a photoelectric conversion device 100; FIG. 1B is a plan view on the side (rear side) which is opposite to the side for light reception. FIG. 2 is a cross-sectional view along cut line A-B in FIGS. 1A and 1B. Hereinafter, description is made with reference to these drawings.

In the photoelectric conversion device 100, a photoelectric conversion layer 106 is provided over a surface of a conductive support substrate 102. A first insulating film 104 is provided between the conductive support substrate 102 and the photoelectric conversion layer 106. The first insulating film 104 and the conductive support substrate 102 are attached to the photoelectric conversion layer 106, thereby forming an ionic bond or a covalent bond to form a firm bond. The first insulating film 104 is provided such that the conductive support substrate 102 is not in direct contact with the photoelectric conversion layer 106, by which occurrence of surface recombination of the photoelectric conversion layer 106 can be suppressed.

A opening 112 is provided in the conductive support substrate 102. The opening 112 reaches to a rear surface of the photoelectric conversion layer 106. A rear electrode 114 is provided in accordance with a position of the opening 112.

The rear electrode 114 is in contact with the conductive support substrate 102 and the photoelectric conversion layer 106 in the opening 112. With this structure, the rear electrode 114 electrically connects the photoelectric conversion layer 106 to the conductive support substrate 102. Electrical connection of the rear electrode 114 to the conductive support substrate 102 enables the conductive support substrate 102 to serve not only as a support but also as a rear electrode.

The photoelectric conversion layer 106 is in contact with the first insulating film 104 on the conductive support substrate 102 and is partly in contact with the rear electrode 114, so that the surface recombination rate of the photoelectric conversion layer 106 is decreased. Generally, the surface recombination rate increases when the photoelectric conversion layer 106 is in contact with the conductive support substrate 102 and the rear electrode 114. However, when the area where the photoelectric conversion layer 106 is in contact with the insulating film is increased, the surface level of the photoelectric conversion layer 106 decreases and the surface recombination rate decreases. Note that the surface recombination rate is a parameter which defines carrier loss by recombination on the semiconductor surface.

The photoelectric conversion layer 106 is formed using a semiconductor material. As the semiconductor material, a single crystal semiconductor or a polycrystalline semiconductor is preferably used. As the single crystal semiconductor or the polycrystalline semiconductor, silicon or a semiconductor material containing silicon as a main component is preferably used. This is because they have properties for absorbing light in the wavelength range from visible light to near-infrared light and are abundant natural resources. The photoelectric conversion layer may be formed using an amorphous semiconductor or a compound semiconductor as long as the photoelectric conversion layer can be formed to be firmly attached onto the support substrate.

As a base semiconductor of the photoelectric conversion layer 106, a p-type single crystal semiconductor is preferably used. This is because the minority carrier of the p-type semiconductor is electrons and the diffusion length of electrons is longer than that of holes. That is, electrons and holes generated in the semiconductor can be taken out effectively.

The photoelectric conversion layer 106 includes a semiconductor junction. For example, a p-type first impurity semiconductor layer 120 is provided on the conductive support substrate 102 side of the photoelectric conversion layer 106; accordingly, contact resistance with respect to the rear electrode 114 can be reduced. In that sense, the first p-type impurity semiconductor layer 120 is not necessarily provided entirely over a surface of the photoelectric conversion layer 106 but may be formed selectively in the portion which is in contact with the rear electrode 114. The first p-type impurity semiconductor layer 120 has a conductivity type of P⁺ having the increased P-type impurity concentration, so that an internal electric field can be formed in the photoelectric conversion layer 106.

In the case where the base semiconductor of the photoelectric conversion layer 106 has a p-type conductivity, a second impurity semiconductor layer 122 is formed to have an n-type conductivity. Accordingly, an np junction is formed on the light incidence side, so that electrons and holes can be taken out effectively.

The surface on the light incidence side of the photoelectric conversion layer 106 may be processed to be rough (have a texture structure) so as to reduce reflection.

A surface electrode 126 is provided on the light incidence side of the photoelectric conversion layer 106. The surface electrode 126 has a comb shape or a grid shape, so that the surface resistance of the second impurity semiconductor layer 122 is substantially reduced. In this way, a photoelectric conversion cell in which the rear electrode 114 is in contact with one surface of the photoelectric conversion layer 106 and the surface electrode 126 is in contact with the other surface thereof is formed.

The conductive support substrate 102 is formed using a conductive material. A metal material is typically used as the conductive material; a single metal such as aluminum, titanium, copper, or nickel or an alloy containing at least one of these metals is selected as the metal material. As an iron-based material, a stainless steel plate, or a rolled steel plate or a high-tensile steel plate which is used for a body of automobiles or the like, or the like can be used. It is preferable that the conductive support substrate 102 have a thickness which is equal to or less than 1 mm in terms of lightness of weight and it is more preferable that the conductive support substrate 102 be a plate with a thickness which is equal to or less than 0.6 mm in terms of flexibility.

In the case where the conductive support substrate 102 is flexible, the photoelectric conversion layer 106 may be formed to have a thickness with which the photoelectric conversion layer 106 is bent as well as the conductive support substrate 102. The photoelectric conversion layer 106 with a thickness of about 1 μm to 10 μm can be bent together with the flexible conductive support substrate 102; even with that thickness, the photoelectric conversion layer 106 can absorb light in the wavelength range from visible light to near-infrared light and generate electromotive force.

It is preferable that the first insulating film 104 be formed using an inorganic insulating material in terms of heat resistance and weather resistance. The surface flatness is needed for firm attachment to the photoelectric conversion layer 106. As for the flatness of the first insulating film 104, it is preferable that a mean surface roughness (Ra) be 1 nm or less, more preferably 0.5 nm or less. The “mean surface roughness” in this specification refers to a mean surface roughness obtained by three-dimensionally expanding centerline mean roughness which is defined in HS B0601 so as to be applied to a plane. As the inorganic insulating material, silicon oxide, silicon oxynitride, aluminum oxide, aluminum oxynitride, or the like is applied. The first insulating film 104 is formed using the inorganic insulating material by a vapor deposition method, a sputtering method, a coating method, or the like.

The surface electrode 126 is provided so as to be in contact with the second impurity semiconductor layer 122. The surface electrode 126 is formed using a metal material. As the metal material, aluminum, silver, a solder, or the like can be applied.

The surface electrode 126 formed using a metal material has light-shielding properties, and therefore it is formed in a grid pattern or a lattice pattern so as not to reduce the active area for light reception of the photoelectric conversion layer 106 as much as possible. For example, the surface electrode 126 is formed in the following pattern so as to suppress the resistive loss on the side where the second impurity semiconductor layer 122 is provided as much as possible: thin grid bars (branches) extend from a bus bar (trunk).

In the photoelectric conversion device according to one embodiment, the rear electrode 114 is in contact with the photoelectric conversion layer 106 through the opening 112 in the conductive support substrate 102, by which the rear surface (the surface on the side which is opposite to the light incidence side) of the photoelectric conversion device can be effectively used. Accordingly, in the photoelectric conversion device, the active area which contributes to photoelectric conversion can be increased and the effective output per unit area can be increased.

The first insulating film 104 is formed over one surface of the conductive support substrate 102 and bonded to the photoelectric conversion layer 106; accordingly, the photoelectric conversion device which is thin and lightweight can be provided. The rear electrode 114 is provided on the rear surface of the conductive support substrate 102 and is made to be in contact with the photoelectric conversion layer 106 by the opening 112, so that the bonding strength between the photoelectric conversion layer 106 and the conductive support substrate 102 can be enhanced. That is, since the adhesion (attachment strength) between a metal film and a semiconductor is lower than the adhesion between an insulating film and a semiconductor, the structure according to this embodiment enables prevention of separation of the photoelectric conversion layer 106 from the conductive support substrate 102.

According to one embodiment of the present invention, the photoelectric conversion device which is flexible and includes the photoelectric conversion layer firmly fixed to the support substrate can be provided.

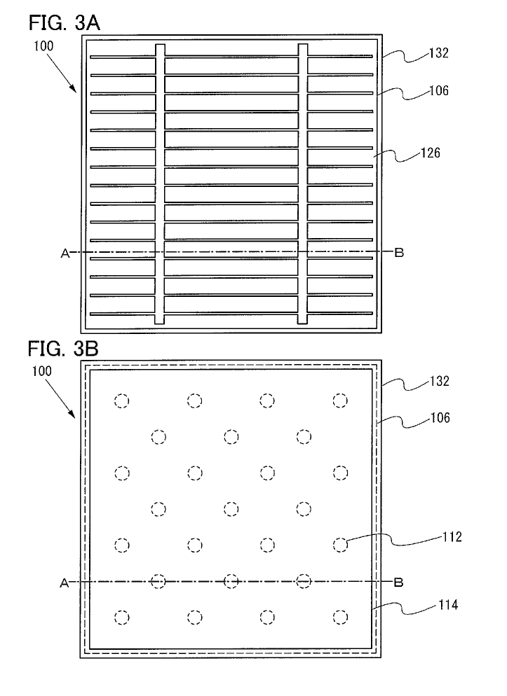

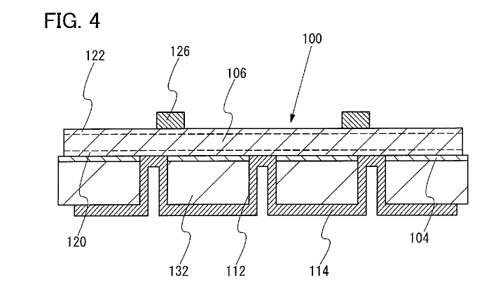

FIGS. 3A and 3B and FIG. 4 illustrate one mode of a photoelectric conversion device in the case where an insulating support substrate 132 is used instead of a conductive support substrate. FIG. 3A is a plan view on the side for light reception of the photoelectric conversion device; FIG. 3B is a plan view on the side (rear side) which is opposite to the side for light reception. FIG. 4 is a cross-sectional view along cut line C-D in FIGS. 3A and 3B. Hereinafter, description is made with reference to these drawings.

The insulating support substrate 132 is formed using a glass material, a plastic material, a ceramic material, or the like. A first insulating film 104 is provided between the insulating support substrate 132 and a photoelectric conversion layer 106. The photoelectric conversion layer 106 is provided over a surface of the insulating support substrate 132 with the first insulating film 104 interposed therebetween. The first insulating film 104 and the insulating support substrate 132 are firmly attached to the photoelectric conversion layer 106, thereby forming an ionic bond or a covalent bond to form a firm bond. The first insulating film 104 is provided such that the insulating support substrate 132 is not in direct contact with the photoelectric conversion layer 106, by which impurity dispersion into the photoelectric conversion layer 106 can be suppressed.

A opening 112 is provided in the insulating support substrate 132. The opening 112 reaches to a rear surface of the photoelectric conversion layer 106. A rear electrode 114 is provided on a surface of the insulating support substrate 132 on the side which is opposite to the side where the photoelectric conversion layer 106 is provided. The rear electrode 114 is in contact with the photoelectric conversion layer 106 in the opening 112. In the case where a first impurity semiconductor layer 120 is provided in the photoelectric conversion layer 106, the rear electrode 114 is in contact with the first impurity semiconductor layer 120.

In the case where the area of the photoelectric conversion layer 106 is 100 mm² or more, it is preferable that a plurality of openings 112 be provided in the insulating support substrate 132. The rear electrode 114 is made to be in contact with the photoelectric conversion layer 106 in each of the plurality of openings 112, thereby reducing power loss caused by series resistance. According to the above structure, the area where the rear electrode 114 and the photoelectric conversion layer 106 are in contact with each other is reduced, so that occurrence of surface recombination of carriers is suppressed.

The other details of this embodiment are the same as the photoelectric conversion device shown in FIGS. 1A and 1B and FIG. 2, and the same or substantially the same effect as the effect thereof is brought. In the photoelectric conversion device according to this embodiment, further reduction in weight and thickness can be achieved by using the insulating support substrate 132.

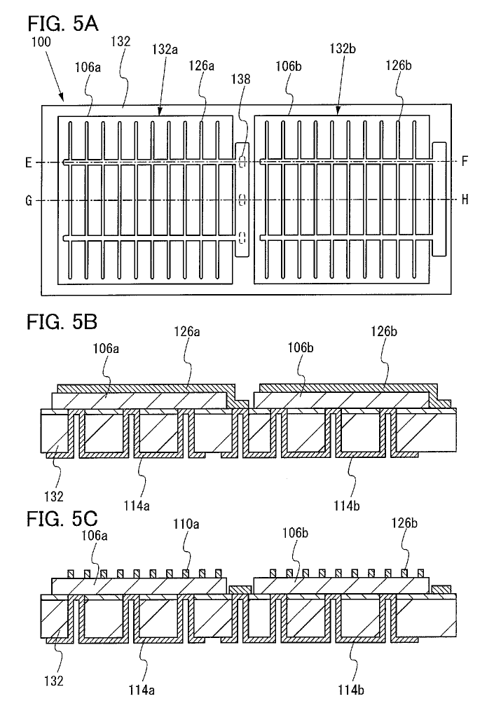

A photoelectric conversion device according to one embodiment of the present invention may include a plurality of photoelectric conversion layers which is provided on a conductive support substrate or an insulating support substrate. One mode of such a photoelectric conversion device is described using FIGS. 5A to 5C.

FIG. 5A is a plan view of a photoelectric conversion device in which a plurality of photoelectric conversion layers is provided on an insulating support substrate; FIG. 5B is a cross-sectional view along cut line E-F in FIG. 5A; FIG. 5C is a cross-sectional view along cut line G-H in FIG. 5A.

In a photoelectric conversion device 100 illustrated in FIGS. 5A to 5C, a first photoelectric conversion layer 106a and a second photoelectric conversion layer 106b are disposed side by side on an insulating support substrate 132. A first rear electrode 114a and a first surface electrode 126a are in contact with the first photoelectric conversion layer 106a. Similarly, a second rear electrode 114b and a second surface electrode 126b are in contact with the second photoelectric conversion layer 106b.

In FIGS. 5B and 5C, a connection portion 138 is a region where the first surface electrode 126a and the second rear electrode 114b are connected to each other via a opening 112 formed in the insulating support substrate 132. That is, in this embodiment, a first photoelectric conversion cell 132a including the first photoelectric conversion layer 106a and a second photoelectric conversion cell 132b including the second photoelectric conversion layer 106b are connected in series by the connection portion 138.

The diameter of the opening 112 in this connection portion 138 may be as small as 50 μm to 400 μm as described above; therefore, the distance between the first photoelectric conversion layer 106a and the second photoelectric conversion layer 106b can be decreased. With such a connection portion, the photoelectric conversion cells provided on the support substrate can be connected to each other, and the distance between the photoelectric conversion cells adjacent to each other can be decreased.

In the photoelectric conversion device according to one embodiment illustrated in FIGS. 5A to 5C, the first surface electrode 126a is connected to the second rear electrode 114b in the connection portion 138, by which the rear surface (the surface on the side which is opposite to the light incidence side) of the photoelectric conversion device can be effectively used and the photoelectric conversion cells can be connected in series. Accordingly, in the photoelectric conversion device, the active area which contributes to photoelectric conversion can be increased and the effective output per unit area can be increased.

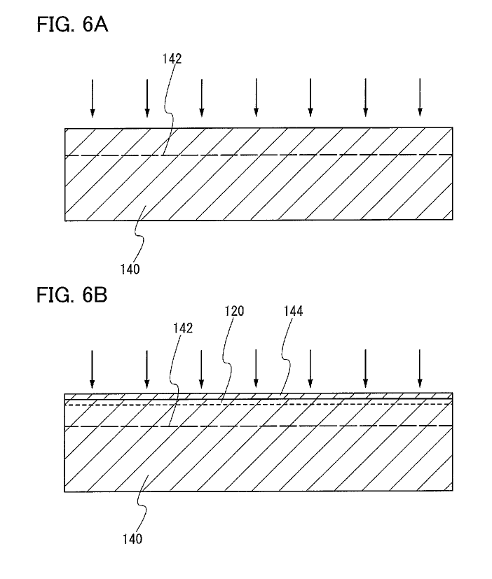

Next, a method for manufacturing a photoelectric conversion device according to one embodiment of the present invention will be described using FIGS. 6A and 6B, 7A and 7B, 8A ad 8B, and 9A and 9B.

Described in this embodiment is the case where a photoelectric conversion layer is formed using a single crystal semiconductor. The photoelectric conversion layer is formed by making a thin layer out of a single crystal substrate. As the method for making a thin layer out of a single crystal semiconductor substrate, a method of polishing a single crystal semiconductor substrate to form a thin layer, a method of etching a single crystal semiconductor substrate to form a thin layer, or the like can be given; in this embodiment, a method is described, in which an embrittlement layer is formed at a predetermined depth in a single crystal semiconductor substrate, so that a thin layer is made out of the single crystal semiconductor substrate.

FIG. 6A illustrates a step in which an embrittlement layer 142 is formed in a semiconductor substrate 140. A single crystal silicon substrate is typically used as the semiconductor substrate 140. Any other bulk semiconductor substrate such as a silicon germanium substrate or a polycrystalline silicon substrate can be used as well.

The conductivity type of the semiconductor substrate 140 can be either one of an n-type or a p-type. It is preferable that the conductivity type of the semiconductor substrate 140 be a p-type. This is because the minority carrier of the p-type semiconductor is electrons and the diffusion length of electrons is longer than that of holes. It is preferable that the resistivity of the semiconductor substrate 140 be in the range of 0.1 Ωcm to 1 Ωcm. This is because the high resistivity of the substrate decreases the carrier lifetime.

The form (e.g., shape, size, and thickness) of the semiconductor substrate 140 is not particularly limited. For example, a semiconductor substrate the planar shape of which is round or has an angle can be used. The thickness of the semiconductor substrate 140 may be based on the SEMI Standard or may be adjusted as appropriate when being cut out from an ingot. The single crystal semiconductor substrate may be cut out from an ingot so as to have a large thickness, so that a cutting margin, that is, a waste of a material can be reduced. As examples of the diameter of the semiconductor substrate 140, the following can be given: 100 mm (4 inches); 150 mm (6 inches); 200 mm (8 inches); 300 mm (12 inches); 400 mm (16 inches); and 450 mm (18 inches). As the semiconductor substrate 140, a semiconductor substrate having a large area is advantageous in increasing the size of a photoelectric conversion module.

The embrittlement layer 142 is formed at a predetermined depth from one surface of the semiconductor substrate 140. The embrittlement layer 142 is provided, at which a superficial portion of the semiconductor substrate 140 is separated to form a semiconductor layer. The semiconductor layer serves as a photoelectric conversion layer.

As a method for forming the embrittlement layer 142, either of an ion implantation method and an ion doping method that are methods in which irradiation is performed with ions accelerated by a voltage can be used. According to these methods, an ionized element is introduced into a region at a predetermined depth from the surface of the semiconductor substrate 140, so that the high concentration impurity region is formed. In this manner, a region in which the crystal structure is broken to be embrittled (an embrittled region) is formed in the semiconductor substrate 140.

In this specification, the “ion implantation” refers to a method in which ions generated from a source gas are mass-separated to irradiate an object so that an ionized element obtained through the mass separation is added, whereas the “ion doping” refers to a method in which ions generated from a source gas are not mass-separated to irradiate an object so that an element of the ions is added.

As an example, hydrogen, helium, or halogen is introduced into the semiconductor substrate 140, so that the embrittlement layer 142 is formed. In FIG. 6A, ions accelerated by an electric field irradiate one surface of the semiconductor substrate 140, thereby forming the embrittlement layer 142 at a predetermined depth of the semiconductor substrate 140. Specifically, the semiconductor substrate 140 is irradiated with ions (typically, hydrogen ions) accelerated by an electric field, thereby introducing a monoatomic ion or a polyatomic ion (also called a cluster ion) into the semiconductor substrate 140. In this manner, the crystal structure of a part of the semiconductor substrate 140 is broken so as to be embrittled, thereby forming the embrittlement layer 142.

The depth at which the embrittlement layer 142 is formed in the semiconductor substrate 140 (here, the depth from the irradiated surface of the semiconductor substrate 140 to the embrittlement layer 142 in the film thickness direction) is determined by controlling the voltage for accelerating irradiation ions and/or the tilt angle (the tilt angle of the substrate). Therefore, in consideration of the thickness of the semiconductor layer to be obtained, the voltage for accelerating irradiation ions and/or the tilt angle are/is determined.

As an irradiation ion, a hydrogen ion is preferably used. Hydrogen is introduced to a predetermined depth of the semiconductor substrate 140, by which the embrittlement layer 142 is formed at the depth. For example, hydrogen plasma is generated from a hydrogen gas, and ions generated in the hydrogen plasma are accelerated by an electric field and irradiate the semiconductor substrate 140, whereby the embrittled layer 142 can be formed. Instead of hydrogen, either helium and hydrogen or helium may be used as a source gas to generate ions, so that the embrittlement layer 142 is formed. A protective layer may be formed on the surface of the semiconductor substrate 140 which is irradiated with the ions, in order to prevent damage to the semiconductor substrate 140.

It is preferable that the hydrogen atomic concentration of the embrittlement layer 142 be 1×10¹⁹ atoms/cm³ or more at their peak. A part of the region of the semiconductor substrate 140 contains hydrogen at such a concentration, so that the crystal structure of the part of the region is broken to become a porous structure in which microvoids are formed. When thermal treatment is performed at relatively low temperatures (about 700° C. or less), there is a change in the volume of the microvoids in the embrittlement layer 142, which results in a crack at or near the embrittlement layer 142.

FIG. 6B illustrates a step in which a second insulating film 144 and a one-conductivity-type first impurity semiconductor layer 120 are formed. There is no limitation on the material for forming the second insulating film 144 as long as it is an insulating film; a film having a smooth and hydrophilic surface may be used. As for the smoothness of the second insulating film 144, the mean surface roughness (Ra) is preferably less than or equal to 1 nm, more preferably less than or equal to 0.5 nm. The “mean surface roughness” in this specification refers to a mean surface roughness obtained by three-dimensionally expanding centerline mean roughness which is defined by JIS B0601 so as to be applied to a plane. For example, the second insulating film 144 is formed using an insulating film such as a silicon oxide film, a silicon oxynitride film, a silicon nitride oxide film, or a silicon nitride film. The second insulating film 144 is not necessarily provided.

In FIG. 6B, the one-conductivity-type first impurity semiconductor layer 120 is formed in the semiconductor substrate 140. In the case where the semiconductor substrate 140 has a p-type conductivity, boron is added as the one-conductivity-type impurity, so that the conductivity type of the first impurity semiconductor layer 120 is p-type. The first impurity semiconductor layer 120 is disposed on the side opposite to the light incidence side to form a back surface field (BSF) in the photoelectric conversion device according to this embodiment. The addition of boron is performed using an ion doping apparatus in which a substrate is irradiated with a generated ion flow that is generated from source gases of B₂H₆ and BF₃ and accelerated by an electric field, without mass separation.

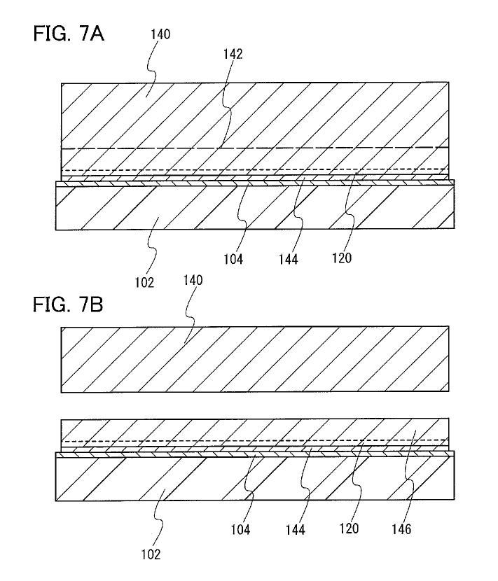

FIG. 7A illustrates a step in which the surface where the second insulating film 144 is formed of the semiconductor substrate 140 is attached to one surface of a conductive support substrate 102. A first insulating film 104 is formed on the one surface of the conductive support substrate 102. The first insulating film 104 is manufactured in the same or substantially the same manner as the manner of the second insulating film 144.

The first insulating film 104 provided for the conductive support substrate 102 and the second insulating film 144 provided for the semiconductor substrate 140 have hydrophilic surfaces; a hydroxyl group or a water molecule serves as an adhesive, a water molecule is dispersed by thermal treatment later performed and silanol groups (Si—OH) of remaining components are bonded to each other by a hydrogen bond. Further, this bonding portion forms a siloxane bonding (O—Si—O) by release of hydrogen to have a covalent bond, whereby the bonding can be further strengthened. As for the hydrophilic properties of the first insulating film 104 and the second insulating film 144, it is preferable that the contact angles to pure water be less than or equal to 20°, more preferably less than or equal to 10°, further more preferably less than or equal to 5°. If the bonding planes are attached under the above conditions, they are attached well, whereby the bonding can be further strengthened.

Irradiation treatment with an atomic beam or an ion beam, a plasma treatment, or a radical treatment may be performed on the surface of the first insulating film 104 and/or the surface of the second insulating film 144 before the attachment of the conductive support substrate 102 to the semiconductor substrate 140. With such a treatment, the bonding plane(s) can be activated so that the attachment can be performed well. For example, the bonding plane can be activated by being irradiated with an inert gas neutral atomic beam or an inert gas ion beam of argon or the like or activated by being exposed to oxygen plasma, nitrogen plasma, oxygen radicals, or nitrogen radicals. With the bonding plane(s) activated, the bonding can be made at low temperatures (for example, 400° C. or less). The surface of the first insulating film 104 and/or the surface of the second insulating film 144 may be processed with ozone-added water, oxygen-added water, hydrogen-added water, pure water, or the like to be hydrophilic so that the number of hydroxyls on the bonding plane(s) is increased, thereby forming a firm bond.

Although the mode in which the first insulating film 104 and the second insulating film 144 are in contact with each other to be bonded to each other is described in this embodiment, the second insulating film 144 is not necessarily provided as long as a flat hydrophilic surface can be obtained.

It is preferable that thermal treatment and/or pressure treatment be performed in the state where the semiconductor substrate 140 and the conductive support substrate 102 overlap each other. Heat treatment and/or pressure treatment performed in that state can increase the adhesion strength. The temperature of the thermal treatment is equal to or less than the strain point of the conductive support substrate 102 and is a temperature at which separation from the embrittlement layer 142 formed in the semiconductor substrate 140 does not occur. For example, the temperature of the thermal treatment is equal to or greater than 200° C. and less than 410° C. When the pressure treatment is performed, pressure is applied in a direction perpendicular to the bonding planes of the conductive support substrate 102 and the semiconductor substrate 140.

FIG. 7B illustrates a step in which the semiconductor substrate 140 is separated out of the conductive support substrate 102 by using the embrittlement layer 142. With thermal treatment at a temperature of 410° C. or more, the volume of the microvoids in the embrittlement layer 142 changes, which brings division at or near the embrittlement layer 142. Since the semiconductor substrate 140 is fixed to the conductive support substrate 102, a semiconductor layer 146 is left on the conductive support substrate 102. The thermal treatment is performed with an electric furnace (furnace), a rapid thermal anneal (RTA) furnace, a dielectric heater using high-frequency waves such as microwaves or millimeter waves with a high-frequency apparatus, or the like. Laser beam irradiation or heat plasma jetting may be performed.

The thickness of the semiconductor layer 146 which is separated out of the semiconductor substrate 140 is 0.5 μm to 10 μm, preferably 1 μm to 5 μm.

Through the above process, the semiconductor layer 146 can be provided on the conductive support substrate 102. In the semiconductor layer 146, a crystal defect caused by the formation of the embrittlement layer 142 may be left and an amorphous region may be formed. Repair of such a crystal defect or such an amorphous region can be performed by thermal treatment. The thermal treatment may be performed at 500° C. to 700° C. with an electric furnace or the like. The semiconductor layer 146 may be irradiated with a laser beam to perform the repair of the crystal defect or the amorphous region. With the laser beam irradiation to the semiconductor layer 146, at least the surface side of the semiconductor layer 146 is melted, and can be recrystallized to become a single crystal in the following cooling step, using a lower portion of the semiconductor layer 146 in a solid-phase state as a seed crystal.

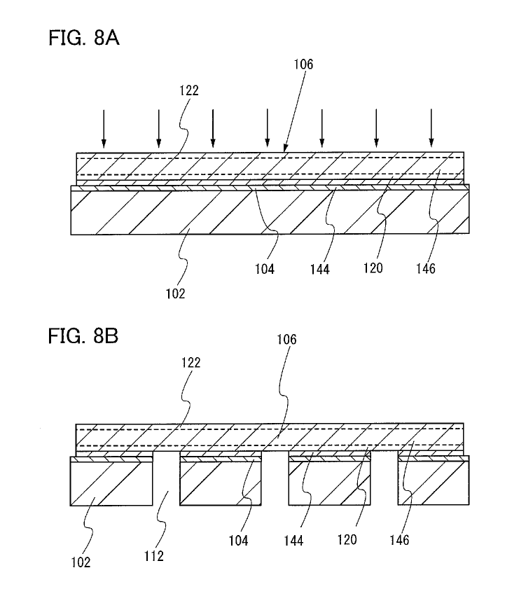

FIG. 8A illustrates a step in which an impurity having a conductivity type which is opposite to the conductivity type of the first impurity semiconductor layer 120 is added to the semiconductor layer 146, so that a second impurity semiconductor layer 122 is formed. Because the first impurity semiconductor layer 120 is formed to have the p-type conductivity in this embodiment, the second impurity semiconductor layer 122 is formed to have an n-type conductivity by adding phosphorus or arsenic. The addition of the impurity into the semiconductor layer 146 is performed by an ion implantation method or an ion doping method. As another method for forming the second impurity semiconductor layer 122, an n-type semiconductor film may be deposited on the semiconductor layer 146.

The second impurity semiconductor layer 122 is provided in the semiconductor layer 146, so that a photoelectric conversion layer 106 is obtained. As described above, the first impurity semiconductor layer 120 may be formed in the semiconductor layer 146 in order to increase the internal electric field. A semiconductor layer including such a semiconductor junction is called the “photoelectric conversion layer” for convenience in this specification.

The semiconductor substrate 140 after the semiconductor layer 146 is separated out by the embrittlement layer 142 can be reused by reprocessing treatment; it may be used as a single crystal semiconductor substrate in manufacturing a photoelectric conversion device or may be used for any other application. The semiconductor substrate 140 may be used repeatedly by reprocessing treatment to form the semiconductor layer 146, which enables formation of a plurality of photoelectric conversion layers from one semiconductor substrate (mother substrate).

FIG. 8B illustrates a step in which a opening 112 is formed in the conductive support substrate 102. A rear surface of the conductive support substrate 102 (a surface on the side which is opposite to the side of the surface where the photoelectric conversion layer 106 is formed) is processed so that the opening 112 which reaches to a rear surface of the photoelectric conversion layer 106 is formed. The formation of the opening 112 in the conductive support substrate 102 is performed by etching of the conductive support substrate 102 and the first insulating film 104. The conductive support substrate 102 and the first insulating film 104 may be partly removed by laser processing to expose the rear surface of the photoelectric conversion layer 106.

It is preferable that a plurality of opening 112 be provided in the conductive support substrate 102. The form of the opening 112 is not particularly limited. For example, when the shape of the opening 112 is a circular shape, the diameter thereof may be 50 μm to 400 μm and the distance between the openings 112 may be 500 μm to 2000 μm. The diameter and the distance between the openings 112 are preferably within the above-described ranges because the mechanical strength of the conductive support substrate 102 decreases as the diameter of the opening 112 formed in the conductive support substrate 102 increases and the number of openings 112 increases.

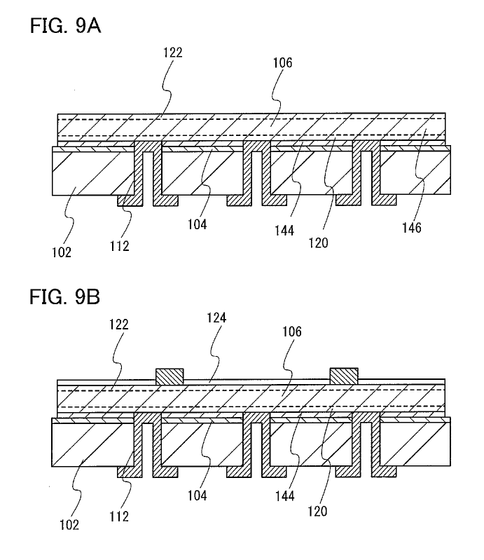

FIG. 9A illustrates a step in which a rear electrode 114 is formed. The rear electrode 114 is formed so as to be in contact with the conductive support substrate 102 and the photoelectric conversion layer 106 exposed through the opening 112 and is electrically connected thereto. The rear electrode 114 may be formed using aluminum, silver, a solder, or the like. For example, the rear electrode 114 is formed by a screen printing method using a silver paste.

FIG. 9B illustrates a step in which a surface electrode 126 and an antireflection film 124 are formed. The surface electrode 126 is formed using a metal material like the rear electrode 114. For example, the surface electrode 126 is formed by a screen printing method using a silver paste to have a comb shape or grid shape.

The antireflection film 124 is formed by depositing an insulating film by a sputtering method, a vapor deposition method (a CVD method), or the like. For example, a silicon nitride film is formed by a plasma CVD method as the antireflection film 124. The antireflection film 124 is provided as needed.

In this manner, the photoelectric conversion device according to this embodiment is manufactured. According to this embodiment, the thin semiconductor layer is bonded to the conductive support substrate, whereby the thin photoelectric conversion device can be obtained. A flexible substrate can be used as the conductive support substrate; in that case, the photoelectric conversion device can be flexible while a crystal semiconductor layer is used.

The conductive support substrate is used in the process described using FIGS. 6A, 6B, 7A, 7B, 8A, 8B, 9A, and 9B; a photoelectric conversion device can be manufactured in a similar manner even in the case of using an insulating support substrate instead of the conductive support substrate. A glass substrate, a plastic substrate, a ceramic substrate, or the like may be used as the insulating support substrate, with which a photoelectric conversion device like the photoelectric conversion device shown in FIG. 4 can be manufactured.

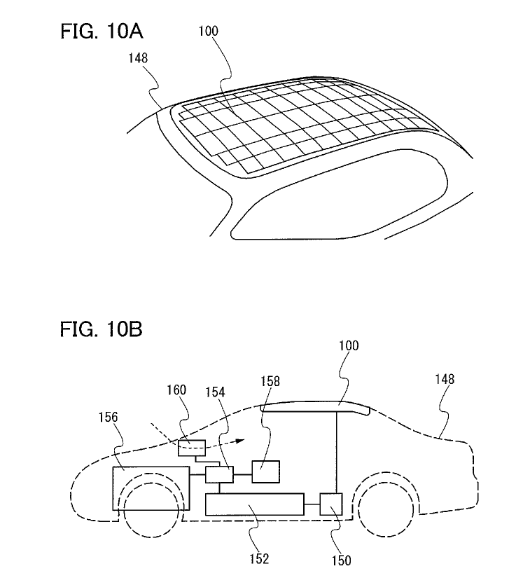

FIGS. 10A and 10B illustrate the case where the photoelectric conversion device manufactured according to the above-described method is provided for vehicles. FIG. 10A illustrates an example in which a photoelectric conversion device 100 is provided at a roof of a vehicle 148. The photoelectric conversion device 100 has the structure in which a photoelectric conversion layer is provided for a conductive support substrate or an insulating support substrate as described above. For example, as shown in FIGS. 5A to 5C, a plurality of photoelectric conversion layers may be disposed on a support substrate.

According to one mode of this embodiment, a flexible support substrate can be used, which enables the photoelectric conversion device 100 itself to be flexible. Therefore, the photoelectric conversion device 100 can be provided along the curved surface shape of the roof of the vehicle. Accordingly, the photoelectric conversion device can be provided for the vehicle without impairing aerodynamic capability or sensuousness based on the appearance configuration of the vehicle; the same can be applied to any other structure. Although the photoelectric conversion device 100 is provided at the roof of the vehicle 148 in FIG. 10A, the photoelectric conversion device 100 can be provided at a hood, a trunk, a door, or the like thereof as well.

A transparent insulating support substrate may be used, a photoelectric conversion layer may be formed to have a thickness of 1 μM or less, and a surface electrode and a rear electrode may be formed using a transparent conductive material, so that a light-transmissive photoelectric conversion device can be formed. In addition, such a photoelectric conversion device may be used at the roof of the vehicle 148 as shown in FIG. 10A, thereby being used also as a co-called sunroof.

FIG. 10B illustrates one example of the structure of the vehicle 148 using the photoelectric conversion device 100. A power storage device 152 is charged with electric power which is generated by the photoelectric conversion device 100 and passes through a charge control circuit 150. The electric power of the power storage device 152 is controlled by a control circuit 154 to be output and is supplied to a driving device 156. The control circuit 154 is controlled by a computer 158.

The power storage device 152 includes a lead battery, a nickel-metal-hydride battery, a lithium-ion battery, a lithium-ion capacitor, or the like. The driving device 156 includes a DC or AC motor either alone or in combination with an internal-combustion engine. The computer 158 outputs a control signal to the control circuit 154 based on an input signal such as operation data (e.g., acceleration, deceleration, or stop) of a driver or data during driving (e.g., a load on a driving wheel, such as an upgrade or a downgrade) of the vehicle 148. The control circuit 154 adjusts the electric energy supplied from the power storage device 152 in accordance with the control signal of the computer 158 to control the output of the driving device 156. In the case where the AC motor is mounted, an inverter which converts direct current into alternate current is incorporated. An air conditioner 160 for ventilating the vehicle 148 can be driven during the parking by using the photoelectric conversion device 100.

The photoelectric conversion device according to this embodiment is advantageous over thin-film photoelectric conversion devices using a glass substrate in terms of high output and reduction in thickness and weight. The photoelectric conversion device according to this embodiment enables electric vehicles or hybrid vehicles to have lighter weight. Since the photoelectric conversion layer of the photoelectric conversion device is formed using a crystalline semiconductor, high output can be attained.

This application is based on Japanese Patent Application serial no. 2009-136279 filed with Japan Patent Office on Jun. 5, 2009, the entire contents of which are hereby incorporated by reference.

What is claimed is:

1. A photoelectric conversion device comprising:
a first insulating film provided on one surface of a conductive support substrate;
a photoelectric conversion layer provided on and in contact with the first insulating film;
a rear electrode which is provided in accordance with an opening which passes through the conductive support substrate and the first insulating film to reach the photoelectric conversion layer, with the rear electrode in contact with the conductive support substrate and the photoelectric conversion layer; and
a surface electrode which is provided on a surface of the photoelectric conversion layer on a side which is opposite to the conductive support substrate.

2. The photoelectric conversion device according to claim 1, wherein a second insulating film is interposed between the first insulating film and the photoelectric conversion layer.

3. The photoelectric conversion device according to claim 1, wherein the conductive support substrate is flexible.

4. The photoelectric conversion device according to claim 2, wherein the conductive support substrate is flexible.

5. The photoelectric conversion device according to claim 1, wherein the photoelectric conversion layer is a single crystal semiconductor.

6. The photoelectric conversion device according to claim 2, wherein the photoelectric conversion layer is a single crystal semiconductor.

7. The photoelectric conversion device according to claim 3, wherein the photoelectric conversion layer is a single crystal semiconductor.

8. The photoelectric conversion device according to claim 4, wherein the photoelectric conversion layer is a single crystal semiconductor.

9. A photoelectric conversion device comprising:
a first insulating film provided on one surface of an insulating support substrate;
a photoelectric conversion layer provided on and in contact with the first insulating film;
a rear electrode which is provided in accordance with an opening which passes through the insulating support substrate and the first insulating film to reach the photoelectric conversion layer, with the rear electrode in contact with the photoelectric conversion layer; and
a surface electrode which is provided on a surface of the photoelectric conversion layer on a side which is opposite to the insulating support substrate.

10. The photoelectric conversion device according to claim 9, wherein a second insulating film is interposed between the first insulating film and the photoelectric conversion layer.

11. The photoelectric conversion device according to claim 9, wherein the insulating support substrate is flexible.

12. The photoelectric conversion device according to claim 10, wherein the insulating support substrate is flexible.

13. The photoelectric conversion device according to claim 9, wherein the photoelectric conversion layer is a single crystal semiconductor.

14. The photoelectric conversion device according to claim 10, wherein the photoelectric conversion layer is a single crystal semiconductor.

15. The photoelectric conversion device according to claim 11, wherein the photoelectric conversion layer is a single crystal semiconductor.

16. The photoelectric conversion device according to claim 12, wherein the photoelectric conversion layer is a single crystal semiconductor.

17. A photoelectric conversion device comprising:
a first insulating film provided on one surface of an insulating support substrate;
a first photoelectric conversion layer and a second photoelectric conversion layer provided on and in contact with the first insulating film;
a first rear electrode which passes through the insulating support substrate and the first insulating film so as to be in contact with the first photoelectric conversion layer;
a second rear electrode which passes through the insulating support substrate and the first insulating film so as to be in contact with the second photoelectric conversion layer;
a first surface electrode which is provided on a surface of the first photoelectric conversion layer on a side which is opposite to the insulating support substrate with the first surface electrode in contact with the first photoelectric conversion layer;
a second surface electrode which is provided on a surface of the second photoelectric conversion layer on a side which is opposite to the insulating support substrate with the second surface electrode in contact with the second photoelectric conversion layer; and
a connection portion where the first surface electrode and the second rear electrode are connected to each other by passing through the insulating support substrate.

18. The photoelectric conversion device according to claim 17, wherein a second insulating film is interposed between the first insulating film and the first photoelectric conversion layer and between the first insulating film and the second photoelectric conversion layer.

19. The photoelectric conversion device according to claim 17, wherein the insulating support substrate is flexible.

20. The photoelectric conversion device according to claim 18, wherein the insulating support substrate is flexible.

21. The photoelectric conversion device according to claim 17, wherein the first photoelectric conversion layer and the second photoelectric conversion layer are single crystal semiconductors.

22. The photoelectric conversion device according to claim 18, wherein the first photoelectric conversion layer and the second photoelectric conversion layer are single crystal semiconductors.

23. The photoelectric conversion device according to claim 19, wherein the first photoelectric conversion layer and the second photoelectric conversion layer are single crystal semiconductors.

24. The photoelectric conversion device according to claim 20, wherein the first photoelectric conversion layer and the second photoelectric conversion layer are single crystal semiconductors.
